(19) United States
(12) Patent Application Publication
(10) Pub. No.: US 2008/0157382 A1
(43) Pub. Date: Jul. 3, 2008

(54) DIRECT TERMINATION OF A WIRING METAL IN A SEMICONDUCTOR DEVICE

(76) Inventors: Anil K. Chinthakindi, Haymarket, VA (US); Douglas D. Coolbaugh, Essex Junction, VT (US); Timothy J. Dalton, Ridgefield, CT (US); Ebenezer E. Eshun, Newburgh, NY (US); Anthony K. Stamper, Williston, VT (US); Richard P. Volant, New Fairfield, CT (US)

Correspondence Address: HOFFMAN WARNICK LLC, 75 STATE ST, 14TH FL, ALBANY, NY, 12207, US

(21) Appl. No.: 11/617,202

(22) Filed: Dec. 28, 2006

(51) Int. Cl. H01L 23/48

(52) U.S. Cl. 257/762; 257/E23.01

(57) ABSTRACT

Direct termination of a wiring metal in a semiconductor device. Direct termination of an AlCu stack or an AlCu layer is made with an underlying Cu wiring level. The AlCu stack or AlCu layer covers all of the Cu wiring level such that it has a border that extends beyond all of the wiring to prevent exposure from occurring.

### TECHNICAL FIELD

This disclosure generally relates to packaging of integrated circuits, and more specifically to forming a direct termination of a wiring metal in a semiconductor device.

### BACKGROUND

In semiconductor manufacturing, a fabricated integrated circuit device is usually assembled into a package to be utilized on a printed circuit board as part of a larger circuit. The leads of the package can make electrical contact with the bonding pads of the fabricated integrated circuit device through a metal bond connection or a solder ball connection.

Currently, copper (Cu) and alloys of Cu are used as chip wiring materials because of its improved chip performance and superior reliability as compared to aluminum (Al) and alloys of Al, which have been used in the past. The packaging of integrated circuit devices employing Cu wiring presents a number of technical issues related to the reaction of the Cu with material used in forming wirebonds and controlled collapse chip connection (C4) interconnects with solder balls. Another issue associated with using Cu as a chip wiring material is that it is susceptible to environmental attack and corrosion. These issues make it difficult to form wirebonds or C4s directly on Cu wiring.

One approach that has been used to overcome these issues associated with Cu wiring is to place an Al level over the last Cu wiring level in the integrated circuit device with a via level connecting the Al level to the Cu wiring level. With this approach wirebonds or C4s are made directly through the via level to the underlying Cu wiring. A problem associated with using the via level to make a wirebond or C4 with the Cu wiring level is that the via increases resistance and power between the Al level and the Cu wiring level. In addition, the use of the via level adds complexity and costs to forming wirebonds or C4s.

Therefore, there is a need for an approach that does not rely on using a via to make a wirebond or C4 with a Cu wiring level.

### SUMMARY

In one embodiment, there is a semiconductor device that comprises a semiconductor base. In this embodiment, a dielectric layer is on the semiconductor base and at least one copper wiring level is in the dielectric layer. An aluminum stack wiring level is in direct contact with the at least one copper wiring level, wherein the aluminum stack wiring level covers all of the at least one copper wiring level.

In another embodiment, there is a semiconductor device that comprises a semiconductor base. In this embodiment, a dielectric layer is on the semiconductor base and at least one copper wiring level is in the dielectric layer. A barrier layer is in direct contact with the at least one copper wiring level. An aluminum wiring level is in direct contact with the barrier layer and the at least one copper wiring level, wherein the aluminum wiring level covers all of the barrier layer and the at least one copper wiring level.

In a third embodiment, there is a semiconductor device that comprises a semiconductor base. In this embodiment, a dielectric layer is on the semiconductor base and at least one copper wiring level is in the dielectric layer. In this embodiment, a portion of the at least one copper wiring level protrudes above the dielectric layer. An aluminum stack wiring level is in direct contact with the at least one copper wiring level, wherein the aluminum stack wiring level covers all of the at least one copper wiring level. In addition, the aluminum stack wiring level has a border that extends beyond all of the at least one copper wiring level to prevent exposure from occurring.

### BRIEF DESCRIPTION OF THE DRAWINGS

FIG. 1 shows a cross-sectional view of a portion of a semiconductor device having at least one copper wiring level in a dielectric layer that is on a semiconductor base;

FIG. 2 shows the semiconductor device depicted in FIG. 1 after performing an etching process;

FIG. 3 shows the semiconductor device depicted in FIG. 2 after depositing an Al wiring level;

FIG. 4 shows the semiconductor device depicted in FIG. 3 after forming termination pads and wires; and

FIG. 5 shows an alternative semiconductor device to the one depicted in FIG. 4.

### DETAILED DESCRIPTION

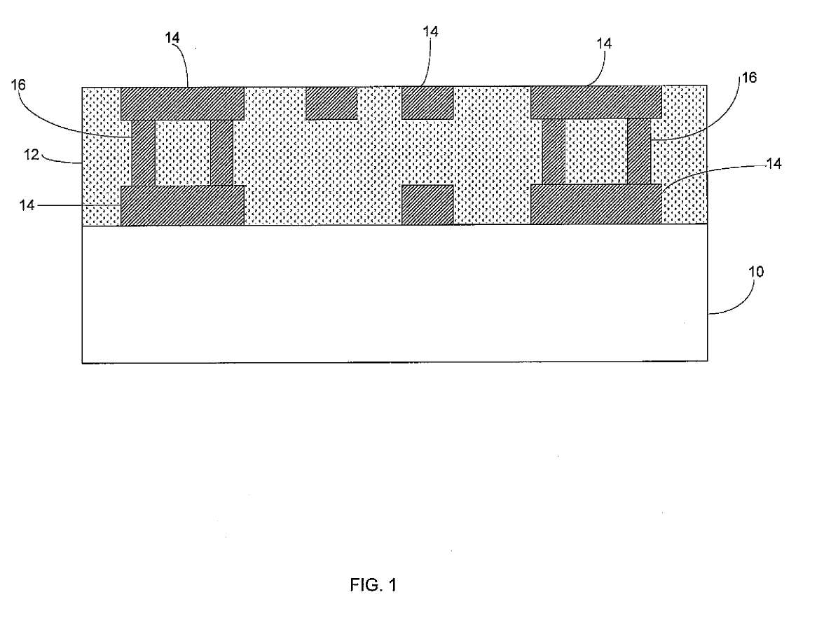

FIG. 1 shows a cross-sectional view of a portion of a semiconductor device having a semiconductor base 10 and a dielectric layer 12 on the semiconductor base. The semiconductor base 10 may comprise integrated circuit devices formed therein. The dielectric layer 12 can comprise any suitable dielectric material such as an oxide, silicon dioxide, fluorinated silicon glass, a nitride, a polymer or low K dielectric.

Within the dielectric layer 12 are horizontally positioned metal levels 14 and 15 made of Cu or an alloy of Cu. Vias 16 made of Cu or an alloy of Cu, connect some of the metal levels 14 in the lower portion of the dielectric layer 12 to the metal levels 15 located directly above in the dielectric. Each of the metal levels 14 and 15 define a Cu wiring level in the dielectric layer 12. The Cu wiring levels within the dielectric layer 12 are used to connect with the integrated circuit devices formed in the semiconductor base 10. Note that not all of the metal levels 14 shown in FIG. 1 are connected to metal levels 15. It is possible that the metal levels 14 and 15 that are shown in FIG. 1 not connected to other metal levels within the dielectric layer 12 may be connected to other devices located above or below the dielectric. The connections of such metal levels 14 and 15 will depend on the circuit design. The semiconductor device shown in FIG. 1 is for illustration purposes and one of ordinary skill in the art will recognize that a device can have substantially more or less Cu wiring levels within the dielectric layer 12.

Damascene processes are used to generate the semiconductor device shown in FIG. 1 once the dielectric layer 12 has been placed on the semiconductor base 10. First, a damascene process is performed to generate a first Cu wiring level in the dielectric layer 12. Typically, in damascene processing, a plasma etch forms openings or trenches in the dielectric layer 12. The openings or trenches are plated with Cu. After depositing the Cu, the damascene processing continues with a chemical mechanical polish (CMP) that planarizes the Cu. Next, more dielectric is deposited to accommodate the vias 16 that will connect the first level of Cu wiring to a second level of Cu wiring. Another damascene process is then performed to generate the second level of Cu wiring and the vias 16 that connect the first and second levels of Cu wiring. In this damascene process, a plasma etch is used to form more openings or trenches in the dielectric layer 12. The openings or trenches are then plated with the Cu and a CMP is used to planarize the second level of Cu wiring. One of ordinary skill in the art will recognize that the damascene process to form the second level of Cu wiring and the vias can be either a single or dual damascene.

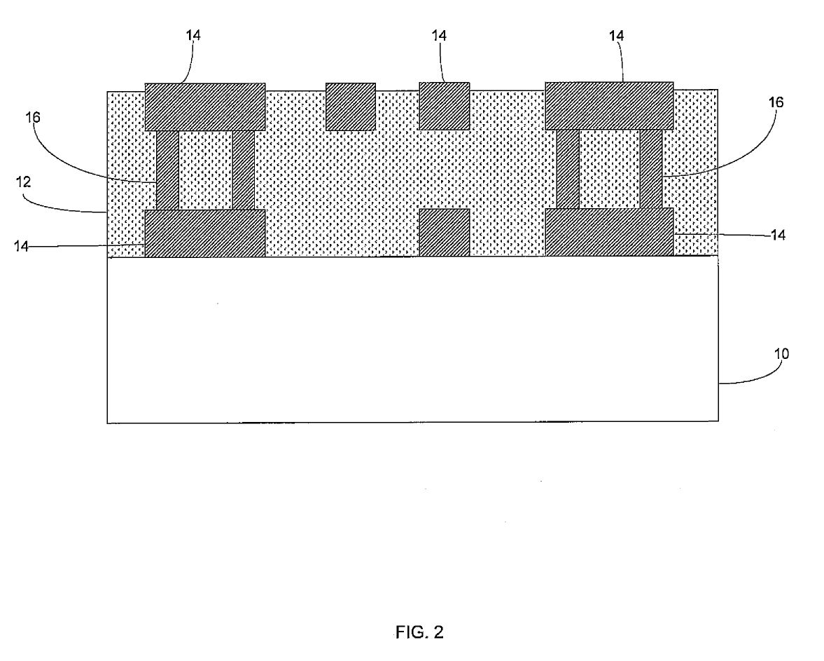

FIG. 2 shows the semiconductor device depicted in FIG. 1 after performing an etching process. In particular, an etching process such as a wet chemical etch is used to recess the dielectric layer 12 below the second level of Cu wiring 15. As a result, the second level of Cu wiring protrudes above the dielectric layer 12. One of ordinary skill in the art will recognize that other etching processes are suitable for use besides a wet chemical etch such as a plasma etch. The protruding second level of Cu wiring forms a step at each of the edges where the Cu wiring level and the dielectric layer meet. The height of the step can range from about 10 nanometers (nm) to about 70 nm, wherein about 50 nm is the preferred height for the step. Instead of having the second Cu wiring level 15 protrude above the dielectric layer 12, it is possible to have the Cu wiring level recessed below the dielectric layer 12.

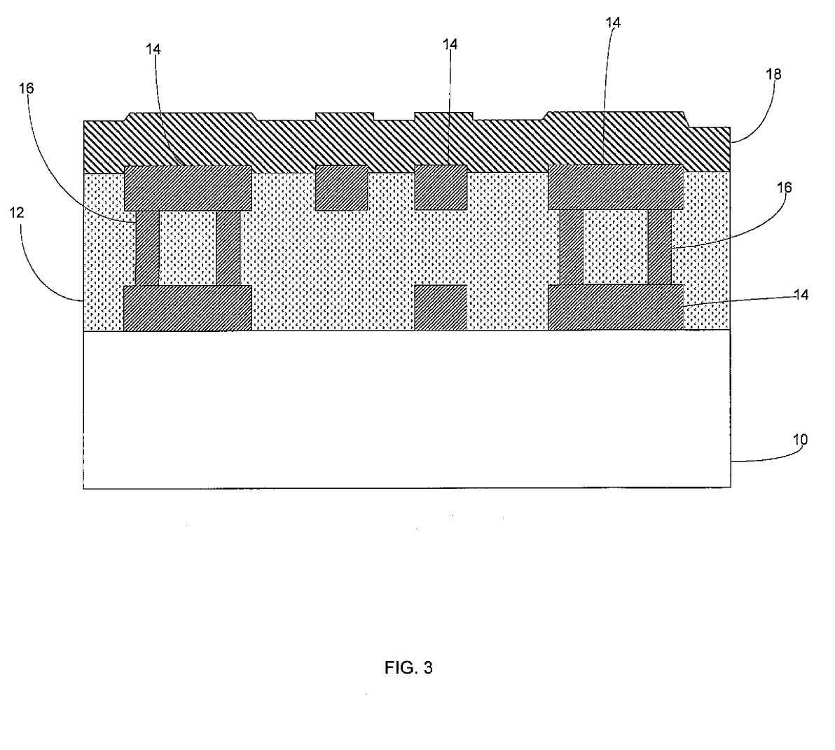

FIG. 3 shows the semiconductor device depicted in FIG. 2 after depositing an Al wiring level 18. In one embodiment, the Al wiring level 18 comprises a stack of aluminum copper (AlCu). As used herein, an AlCu stack denotes a plurality of metallic layers in which the outermost layer contains a layer of AlCu followed by a layer of titanium nitride (TiN). In FIG. 3, the AlCu stack is shown as one layer. In one embodiment, the AlCu stack comprises a layer of tantalum nitride (TaN), a layer of titanium (Ti) on the TaN layer, a layer of TiN on the Ti layer, a layer of AlCu on the TiN layer and a layer of TiN on the AlCu layer (TaN/Ti/TiN/AlCu/TiN). One of ordinary skill in the art will recognize that other combinations of Ta, TaN, Ti and TiN layers can be used with the AlCu layer to form the AlCu stack. Furthermore, one of ordinary skill in the art will recognize that other material suitable for preventing diffusion of Cu and Al can be used in the AlCu stack besides Ta, TaN, Ti and TiN such as Tungsten.

The AlCu stack is formed by utilizing deposition techniques that are well known to those skilled in the art. In one embodiment, sputtering is used to deposit the AlCu stack. The AlCu stack has a thickness that can vary from about 1 micrometer (μm) to about 5 μm. Preferably the AlCu stack has a thickness that can vary from about 2 μm to about 4 μm.

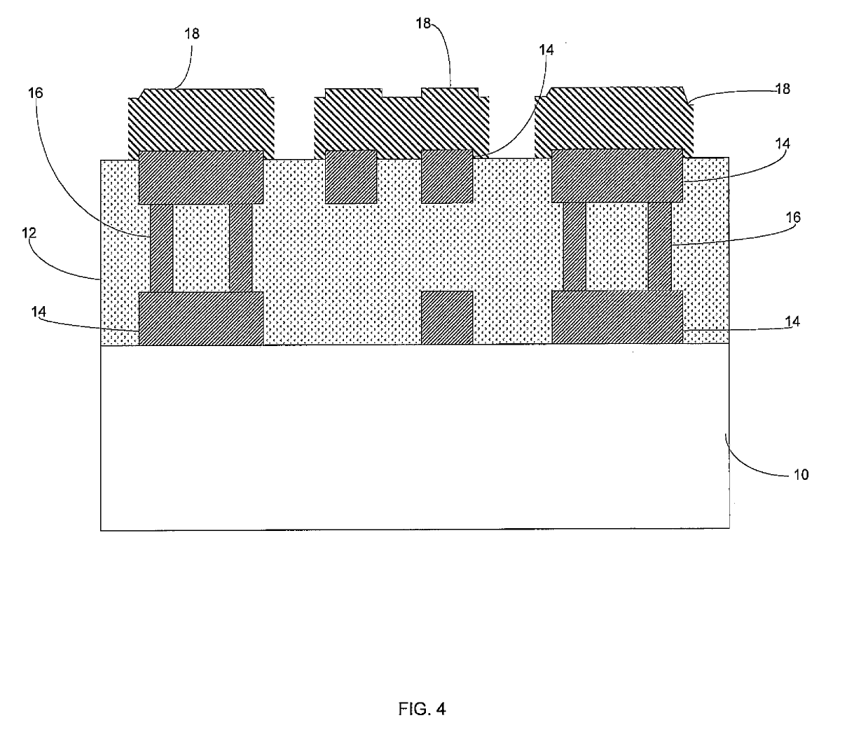

FIG. 4 shows the semiconductor device depicted in FIG. 3 after forming termination pads and wires. Standard lithographic procedures are used to align the AlCu stack to the Cu wiring levels as well as measure the overlay between the two. The topology from the edge that results from the Cu wiring level 15 protruding above the dielectric layer 12 enables a lithographic tool to align the AlCu stack to the Cu wiring. After aligning, the lithographic tool exposes the photoresist on the AlCu stack. Overlay measurement is done to confirm alignment. A reactive ion etch (RIE) is then used to etch the AlCu stack to generate termination pads and wires. A post RIE cleaning is then used to remove any residuals that remain from the RIE. The result from this processing is that the AlCu stacks covers all of the copper wiring level such that it has a border that extends beyond all of the copper wiring to prevent exposure from occurring. Furthermore, direct termination of the AlCu stack is made with the copper wiring. Therefore, when it is time to assemble the semiconductor device into the package, the connection will be made directly to the AlCu stacks which define bonding pads that are in direct termination with the Cu wiring level.

Before a wirebond or C4 is made with the AlCu stacks, a passivating layer (not shown) is formed on the AlCu stacks by utilizing deposition techniques that are well known to those skilled in the art. Inorganic as well as organic passivating materials can be employed as a passivating layer. In one embodiment, the passivating layer comprises a combination of an oxide, a nitride and a polyimide (oxide/nitride/polyimide). Standard lithographic techniques are used to form an opening in the passivating layer that will expose regions of the AlCu stack. The exposed regions of the AlCu stack which are referred to as a termination pad can receive either a wirebond or a C4 solder ball. With a wirebond or C4 solder ball in place, the semiconductor device can then bond to a semiconductor package.

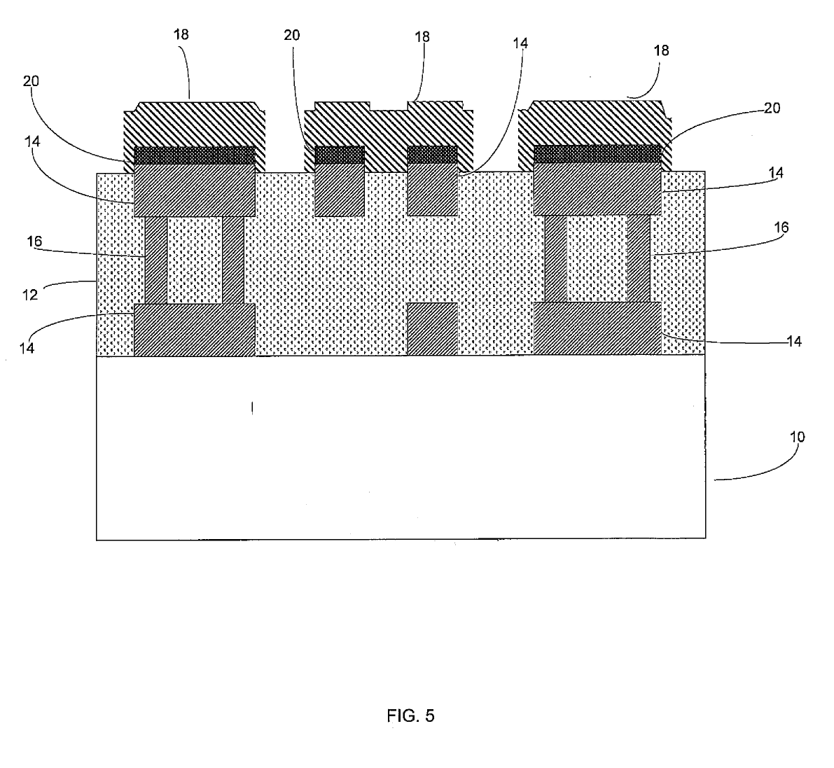

FIG. 5 shows an alternative semiconductor device to the one depicted in FIG. 4. In this embodiment, the semiconductor device has a barrier layer 20 that is placed on and in direct contact with the Cu wiring level 15. The barrier layer 20 can comprise a layer of TaN or a layer of Ta with a layer of TaN on the Ta layer (Ta/TaN). One of ordinary skill in the art will recognize that other combinations of elements can be selected to form the barrier layer 20. The Al wiring level 18 in this embodiment is in direct contact with the barrier layer 20 and the Cu wiring levels 15, wherein the Al wiring level covers all of the barrier layer and the Cu wiring level such that there is a border that extends beyond all of the barrier layer 20 and Cu wiring levels 15 to prevent exposure from occurring.

One can produce the semiconductor device of FIG. 5 by first starting with the device shown in FIG. 1. Instead of using a wet chemical etch to recess the dielectric layer 12 below the Cu wiring levels 15 as in FIG. 2, a wet chemical etch of acetic acid and peroxide is used in this embodiment to recess the Cu wiring levels 15 below the dielectric layer 12. In one embodiment, the Cu wiring levels 15 are recessed an amount that ranges from about 50 nm to about 100 nm with 70 nm being a preferred amount of recess.

After the Cu wiring levels 15 have been recessed, a standard cleaning process is used to clean the recessed Cu wiring levels with a Diluted Hydrofluoric (DHF) acid. Those skilled in the art will recognize that there are other cleaning agents that are compatible with Cu that can be used in the cleaning process. The barrier layer of TaN or Ta/TaN is then deposited to fill the recessed portion thus capping the Cu wiring levels. The barrier layer stack is formed by utilizing deposition techniques that are well known to those skilled in the art such as sputtering.

Next, CMP is performed to remove the barrier layer from in between the Cu wiring level, leaving it only in recessed areas in contact with the Cu. Then a wet chemical etch or RIE is used to recess the dielectric layer 12 below the barrier layer 20. As a result, the barrier layer 20 protrudes above the dielectric layer 12. The protruding barrier layer forms a step at each of the edges where the barrier layer and Cu wiring level meet with the dielectric layer. The height of the step can range from 50 nm to about 100 nm, wherein 70 nm is the preferred height for the step.

After the etching of the dielectric layer, the Al wiring level 18 is deposited. In this embodiment, the Al wiring level 18 comprises AlCu. The AlCu layer is formed by utilizing deposition techniques that are well known to those skilled in the art such as sputtering. The AlCu layer has a thickness that can vary from about 1 μm to about 5 μm. Preferably the AlCu layer has a thickness that can vary from about 2 μm to about 4 μm.

Standard lithographic procedures are used to produce the semiconductor device shown in FIG. 5. In particular, a lithographic tool is used to align the AlCu layer to the barrier layer and the Cu wiring levels as well as measure the overlay. The topology from the edge that results from the barrier layer 20 protruding above the dielectric layer 12 enables the lithographic tool to align the AlCu layer to the Cu wiring and barrier layer. After aligning, the lithographic tool exposes the photoresist on the AlCu layer. Overlay measurement is done to confirm alignment. A RIE is then used to etch the AlCu layer to generate termination pads and wires.

A post RIE cleaning is then used to remove any residuals that remain from the RIE. The result from this processing is that the AlCu layer covers all of the barrier layer and the copper wiring level such that it has a border that extends beyond all of the barrier layer and copper wiring to prevent exposure from occurring. Furthermore, direct termination of the AlCu layer is made with the copper wiring. Therefore, when it is time to assemble the semiconductor device into the package, the connection will be made directly to the AlCu layer which define bonding pads that are in direct termination with the Cu wiring level.

Before a wirebond or C4 can be made with the AlCu layer, a passivating layer is formed on the AlCu layer by utilizing deposition techniques that are well known to those skilled in the art. Inorganic as well as organic passivating materials can be employed as a passivating layer. In one embodiment, the passivating layer comprises a combination of an oxide, a nitride and a polyimide (oxide/nitride/polyimide). Standard lithographic techniques are used to form an opening in the passivating layer that will expose regions of the AlCu layer. The exposed regions of the AlCu layer which are referred to as termination pads can receive either a wirebond or a C4 solder ball. With a wirebond or C4 solder ball in place, the semiconductor device can then bond to a semiconductor package.

An advantage of the semiconductor devices shown in FIGS. 4 and 5 is that the use of a via level to make wirebonds or C4s to the underlying Cu wiring has been avoided. As a result, the semiconductor devices of FIGS. 4 and 5 are less complex and cheaper to produce as compared to devices that rely on a via to make a wirebond or C4 with the Cu wiring. In addition, the semiconductor devices of FIGS. 4 and 5 will have lower resistance, thus improving the performance of inductors and transmission lines (i.e., a higher Q).

It is apparent that there has been provided with this disclosure, an approach for obtaining direct termination of wiring metal in a semiconductor device. While the disclosure has been particularly shown and described in conjunction with a preferred embodiment thereof, it will be appreciated that a person of ordinary skill in the art can effect variations and modifications without departing from the scope of the disclosure.

What is claimed is:

1. A semiconductor device, comprising:
a semiconductor base;
a dielectric layer on the semiconductor base;
at least one copper wiring level in the dielectric layer;
an aluminum stack wiring level in direct contact with the at least one copper wiring level, wherein the aluminum stack wiring level covers all of the at least one copper wiring level.

2. The semiconductor device according to claim 1, wherein the aluminum stack wiring level has a border that extends beyond all of the at least one copper wiring level to prevent exposure from occurring.

3. The semiconductor device according to claim 1, wherein a portion of the at least one copper wiring level protrudes above the dielectric layer.

4. The semiconductor device according to claim 1, wherein the aluminum stack wiring level comprises a layer of TaN, a layer of Ti on the TaN layer, a layer of TiN on the Ti layer, a layer of AlCu on the TiN layer, and a layer of TiN on the AlCu layer.

5. A semiconductor device, comprising:
a semiconductor base;
a dielectric layer on the semiconductor base;
at least one copper wiring level in the dielectric layer;
a barrier layer in direct contact with the at least one copper wiring level; and
an aluminum wiring level in direct contact with the barrier layer and the at least one copper wiring level, wherein the aluminum wiring level covers all of the barrier layer and the at least one copper wiring level.

6. The semiconductor device according to claim 5, wherein the aluminum wiring level has a border that extends beyond all of the barrier layer and the at least one copper wiring level to prevent exposure from occurring.

7. The semiconductor device according to claim 5, wherein the barrier layer comprises a layer of TaN or a layer of Ta with a TaN layer on the Ta layer.

8. The semiconductor device according to claim 6, wherein the aluminum wiring level comprise AlCu.

9. A semiconductor device, comprising:
a semiconductor base;
a dielectric layer on the semiconductor base;
at least one copper wiring level in the dielectric layer, wherein a portion of the at least one copper wiring level protrudes above the dielectric layer;
an aluminum stack wiring level in direct contact with the at least one copper wiring level, wherein the aluminum stack wiring level covers all of the at least one copper wiring level, wherein the aluminum stack wiring level has a border that extends beyond all of the at least one copper wiring level to prevent exposure from occurring.

10. The semiconductor device according to claim 9, wherein the aluminum stack wiring level comprises a layer of TaN, a layer of Ti on the TaN layer, a layer of TiN on the Ti layer, a layer of AlCu on the TiN layer, and a layer of TiN on the AlCu layer.
